(19) United States
(12) Patent Application Publication
(10) Pub. No.: US 2025/0354246 A1
(43) Pub. Date: Nov. 20, 2025

(54) CALCITE CHANNEL NANOFLUIDICS

(71) Applicant: Saudi Arabian Oil Company, Dhahran (SA)

(72) Inventors: Dong Kyu Cha, Dhahran (SA); Subhash Ayirala, Dhahran (SA); Ali Abdallah Al-Yousef, Dhahran (SA)

(21) Appl. No.: 18/663,203

(22) Filed: May 14, 2024

(51) Int. Cl. C23C 14/04; C23C 14/06

(52) U.S. Cl. CPC C23C 14/042; B01L 3/502707; C23C 14/06

(57) ABSTRACT

A method for fabricating calcite channels in a nanofluidic device is described. A photoresist is coated on a substrate, and a portion of the photoresist is then exposed to a beam of electrons in a channel pattern. The exposed portion of the photoresist is developed to form a channel pattern, and calcite is deposited in the channel pattern using pulsed laser deposition. The photoresist remaining after developing the exposed portion of the photoresist is removed.

### TECHNICAL FIELD

This specification relates to nanofluidic devices and techniques and more specifically nanofluidic devices and techniques for petrophysical applications.

### BACKGROUND

Enhanced oil recovery methods can increase the amount of crude oil extracted from an oil field. At small scales (channel sizes on the order or nanometers or micrometers), fluids can behave differently than in macroscopic systems. Factors such as surface tension begin to dominate fluid behavior. With better understanding of fluid behavior at small scales, enhanced oil recovery methods can be improved and more oil extracted from a source rock or reservoir. Microfluidic models that can replicate conditions found in underground reservoirs have been developed to observe, evaluate, and understand physical and chemical phenomena in oil extraction and recovery.

### SUMMARY

The present disclosure describes a method of fabricating calcite channels for nanofluidics. Certain aspects of the subject matter described here can be implemented as a method. Calcite channels are fabricated in a nanofluidic device. A photoresist is coated on a substrate, and a portion of the photoresist is exposed to a beam of electrons in a channel pattern. The exposed portion of the photoresist is developed to form a channel pattern, and calcite is deposited in the channel pattern using a pulsed laser deposition. The photoresist remaining after developing the exposed portion of the photoresist is removed.

This, and other aspects, can include one or more of the following features. The substrate can be silicon. The photoresist can be a negative photoresist, such as polydimethylsiloxane (PDMS) or SU-8. Developing the photoresist can include dissolving the photoresist using a solvent and revealing a portion of the substrate. The solvent used to dissolve the photoresist can be propylene glycol methyl ether acetate (PGMEA), ethyl lactate, or di-acetone alcohol. Fabricating calcite channels in the nanofluidic device can include packaging the device in a casing. The casing can include a top portion which includes a window, a bottom portion to hold the device, an inlet connection to allow a fluid to enter the device, and an outlet connection to allow the fluid to exit the device. The window can be an electrically conductive and optically transparent material, such as silicon nitride (SiN).

The details of one or more implementations of the subject matter of this specification are set forth in the accompanying drawings and the description. Other features, aspects, and advantages of the subject matter will become apparent from the description, the drawings, and the claims.

### DESCRIPTION OF DRAWINGS

FIG. 1 is a schematic diagram illustrating an example method for fabricating a nanofluidic device, according to an implementation.

FIG. 2A is an example schematic cross section of a target in a vacuum chamber head of a PLD apparatus.

FIG. 2B is an example schematic of a PLD apparatus, according to an implementation.

FIG. 3A is a cross-sectional view of a schematic diagram illustrating an example nanofluidic device, according to an implementation.

FIG. 3B is a top view of a schematic diagram illustrating an example nanofluidic device, according to an implementation.

FIG. 4 is a schematic diagram illustrating an example nanofluidic device system, according to an implementation.

FIG. 5 is a flowchart of an example method for fabricating a nanofluidic device, according to an implementation.

FIG. 6 is a flowchart illustrating an example method for fabricating a calcite channel nanofluidic device, according to an implementation.

Like reference numbers and designations in the various drawings indicate like elements.

### DETAILED DESCRIPTION

The following detailed description describes a method of fabricating calcite channels for nanofluidics, and is presented to enable any person skilled in the art to make and use the disclosed subject matter in the context of one or more particular implementations. Various modifications, alterations, and permutations of the disclosed implementations can be made and will be readily apparent to those or ordinary skill in the art, and the general principles defined may be applied to other implementations and applications, without departing from scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

A portion of the world's oil reserves exists in carbonate rocks, such as limestone and dolostone. These rocks, however, can vary considerably in characteristics such as texture, porosity, and permeability even across areas within the same formation. This variation makes consistent flow of oil difficult to achieve. Microfluidic devices and techniques are considered to be useful for characterizing crude oil interactions with different fluids and with rock formations in petrophysics applications. Conventional calcite (CaCO₃) channel models comprise etched natural calcite crystal, but these models are on the scale of micrometers. Fluidics at a nano-scale (that is, on the order of nanometers), are beneficial to understand the physical and chemical phenomena of fluid-fluid and fluid-calcite rock interactions.

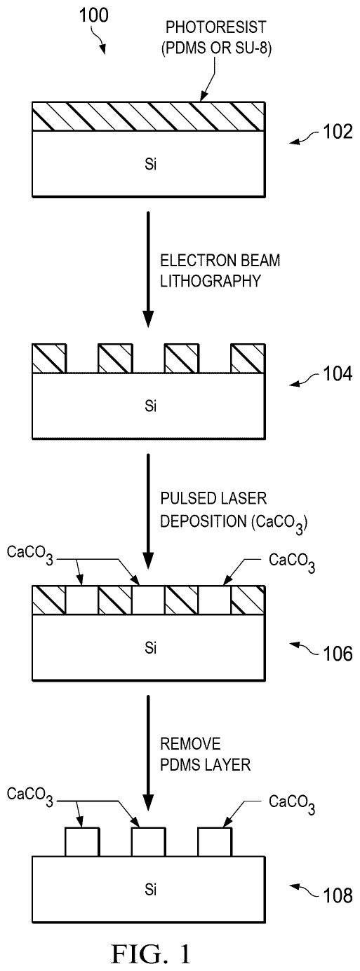

Referring to FIG. 1, a method 100 for fabricating calcite channels in a nanofluidic device includes coating 102 a photoresist on a substrate. In certain implementations, the photoresist is a negative photoresist, such as polydimethylsiloxane (PDMS) or SU-8. The substrate can have a clean and flat surface and can be made of, for example, silicon. The coating of the photoresist can be performed by spin coating to apply a layer of photoresist on the substrate at a spin rate in a range of approximately 500 to 2000 revolutions per minute (rpm). The spin rate can determine the thickness of the layer of photoresist. The thickness of the layer of photoresist can determine a height of resulting calcite channels in the nanofluidic device. Therefore, the thickness of the photoresist coating can be chosen based on the desired height for the calcite channels in the nanofluidic device, for example, a height less than 10 centimeters (cm). The preparation of photoresist can include edge bead removal (EBR) to remove any buildup of photoresist on the edge of the substrate. The preparation of photoresist can include a baking step which involves baking at approximately 200 degrees Fahrenheit (° F.) for a duration of time, dependent on the thickness of the layer of photoresist. The baking temperature can also affect the duration of the baking step.

From 102, method 100 proceeds to 104, where a portion of the photoresist is exposed to a beam of electrons. This exposure causes the portion of the photoresist to be removed. In certain implementations, electron beam lithography is used to remove the photoresist. Electron beam lithography is a technique for patterning at nanometer (nm) scale. A beam of electrons is scanned on a resist, for example, PDMS. This exposes the resist. The exposed resist can be developed to form a pattern in the remaining resist. Other lithographic techniques that expose the resist using other energy sources can be used. In certain electron beam lithography implementations, the beam of electrons is supplied by a scanning electron microscope (SEM). The exposure of the resist can be followed by a post-exposure baking step which involves baking at approximately 200° F. for a duration of time, dependent on the thickness of the layer of photoresist.

The portion of the photoresist that is exposed to the beam of electrons can be exposed in a channel pattern. In general, a portion of the photoresist is exposed to an energy source and developed to form the channel pattern. Sizes of the channel pattern can be chosen based on the desired size for the calcite channels in the nanofluidic device. For positive resists, development of the resist removes the exposed portion of the resist. For negative resists, development of the resist removes the unexposed portion of the resist. Developing the resist generally involves dissolving the resist using a solvent and revealing a portion of a surface of the substrate under the photoresist. In certain implementations, the solvent is an organic solvent, such as propylene glycol methyl ether acetate (PGMEA), ethyl lactate, or di-acetone alcohol. The development time depends on the thickness of the layer of photoresist. The portion of photoresist that remains after development forms an inverse pattern of the calcite channels in the finalized nanofluidic device. After development, the device can be rinsed with fresh solvent, followed by a second wash with another solvent, such as isopropyl alcohol. The device can then be dried with a gas, such as nitrogen.

From 104, method 100 proceeds to 106, where calcite is deposited in the channel pattern. In certain implementations, atomic layer deposition is used to deposit calcite using a calcite precursor gas. Atomic layer deposition is a technique for depositing a material from a vapor phase and includes a sequence of alternating introductions of gaseous chemical precursors that react with the substrate. The individual gas-surface reactions are called half-reactions. During each half-reaction, a precursor gas is introduced for a designated amount of time, to allow the precursor gas to fully react with the substrate surface and deposit a single layer at the surface. The device is then purged with an inert gas, such as nitrogen or argon, to remove unreacted precursor, reaction by-products, or both. The next precursor gas is then introduced to deposit another layer and similarly purged. The process cycles as alternating precursor gas is deposited layer by layer until the desired height is reached. In certain implementations, the atomic layer deposition process can continue until the calcite layers reach a similar or same height as the original coating of photoresist. The deposited calcite can have at least one side with a length in a range of approximately 50 to 100 nm. From 106, method 100 proceeds to 108, where the photoresist remaining after developing the exposed portion of the photoresist in 104 is removed. Removal of the remaining photoresist involves dissolving the photoresist using a solvent, such as the solvent used in developing the resist in 104. The remaining calcite and substrate form the nanofluidic device.

In other implementations, pulsed laser deposition (PLD) is used to deposit calcite in the channel pattern. PLD is a physical vapor deposition technique that can be used to deposit a thin film on a substrate. In some PLD implementations, a vacuum chamber with a chamber window holds a target and the substrate. In certain implementations, the vacuum chamber is depressurized to about 100 Pa or less. A high-power pulsed laser beam is focused through the chamber window to strike the target. In certain implementations, a YAG laser source is used. In certain implementations, the laser wavelength is 523 nm. In certain implementations, the laser pulses are from 2 to 20 ns in duration, for example 5 ns pulse width at a 10 Hz repetition rate or 7 ns pulse width at 10 Hz repetition rate. The laser strikes the target and vaporizes the target, i.e., releases ionized particles from the target. These particles form a plume that deposits a thin film of the particles on the surface of the substrate. Unlike ALD, PLD does not require a precursor gas. Rather, a solid target is the source of the material for the film. Further, the produced plume of particles has the same composition as the target, accordingly, the thin film produced by PLD has the same composition as the target. This simplifies the process and increases efficiency. Further, PLD is faster than other deposition processes, for example ALD.

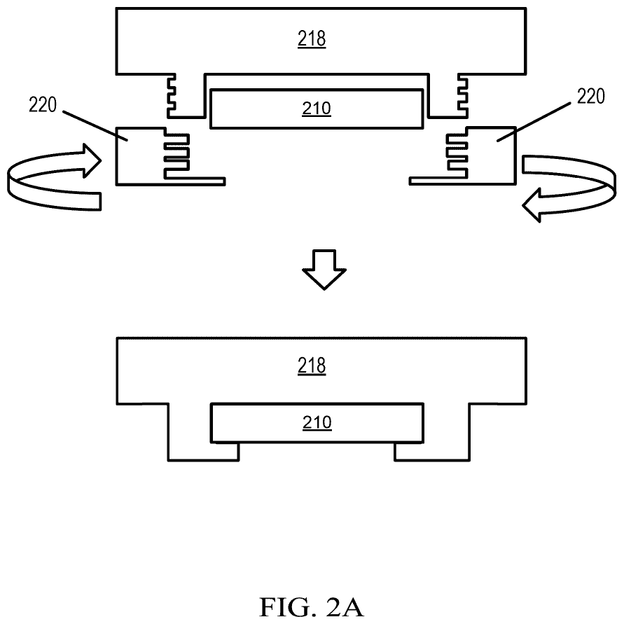

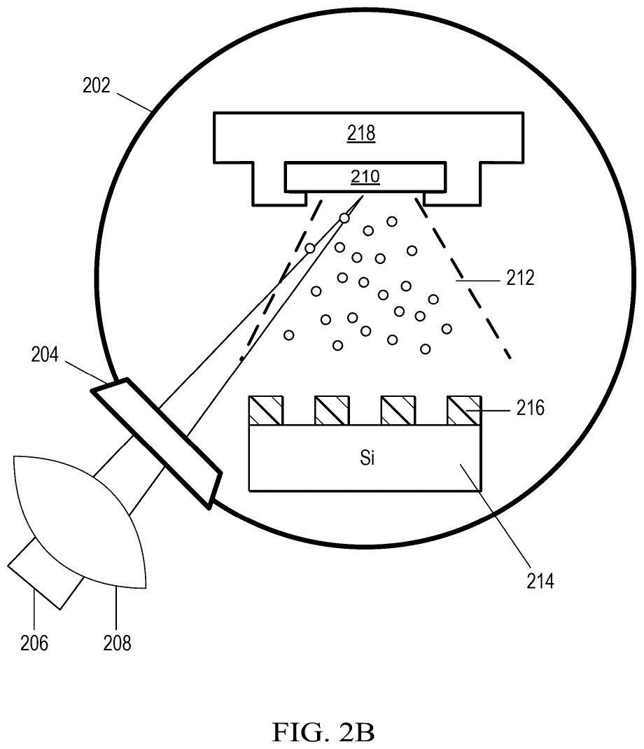

FIG. 2A shows an example schematic cross section of a target in the vacuum chamber head of an PLD apparatus. The vacuum chamber head 218 holds the target 210. In certain implementations, the vacuum chamber head 218 includes a screw cap 220 that can be tightened in place to hold the target 210. FIG. 2B shows an example schematic of a PLD apparatus. The apparatus includes a vacuum chamber 202 with a chamber window 204. In operation, a pulsed laser 206 is focused through a lens 208 and directed through the chamber window 204. The target 210 is held in the vacuum chamber head 218. The laser hits the target 210 and generates a plume 212 of atomized and ionized particles. The plume deposits a thin film on a substrate disposed in the vacuum chamber. For example, the plume can deposit a thin film on the substrate 214 that includes a channel pattern defined by the photoresist 216. Accordingly, PLD can be used to deposit calcite from a target 210 into the channel pattern to form the calcite channels on a substrate. In certain implementations, calcite is deposited layer by layer until the height of the calcite in the channel pattern defined in the photoresist is similar to or the same as the height of the photoresist coating the substrate.

PLD can be used to deposit calcite in the channel pattern of the exposed photoresist on the substrate. For example, PLD can be used with a calcite target and the exposed photoresist-coated substrate. In certain implementations, the calcite target includes solid calcite (CaCO₃). The calcite target is substantially pure CaCO₃. In certain implementations, the calcite targe is 1-2 cm in diameter and 0.5 cm thick. In certain implementations, the calcite target and photoresist-coated substrate are positioned in the vacuum chamber of the PLD apparatus such that the plume of ionized particles generated by the laser expands towards the photoresist-coated substrate. The ionized particles are deposited in the channel pattern of the photoresist-coated substrate, as well as on top of the remaining photoresist. The laser pulses can be repeated to deposit additional calcite in the channel pattern until the deposited calcite reaches the height of the initial photoresist. The photoresist-coated substrate with calcite channels can then be removed from the vacuum chamber. The photoresist is then removed. Removing the photoresist also removes any calcite deposited on top of the photoresist. The photoresist can be removed as described herein, yielding the substrate with calcite channels.

A method for creating a substrate with calcite channels includes coating a photoresist on a substrate, exposing a portion of the photoresist to a beam of electrons, where the portion is exposed in a channel pattern, developing the exposed portion of the photoresist to form the channel pattern, depositing calcite in the channel pattern using pulsed laser deposition, and removing the photoresist remaining after developing the exposed portion of the photoresist. Depositing calcite in the channel pattern using pulsed laser deposition includes placing a calcite target in a vacuum chamber, and placing the substrate with the channel pattern in the vacuum chamber. The substrate is oriented such that the channel pattern on the substrate faces the calcite target. The method includes depressurizing the vacuum chamber, and striking the calcite target with a pulsed laser to generate ionized calcite particles from the calcite target, where the ionized calcite particles are deposited in the channel pattern.

Commercially available systems can be used for a PLD process as described herein. For example, a Pulsed Lase Deposition system from PVD Products or a Handy YAG-Quana system. In certain implementations, the processing time of the PLD process can be varied depending on the desired calcite film thickness. In certain implementations, PLD is conducted with a 10 Hz repetition rate, 5 ns pulse width, and a laser wavelength of 532 nm.

Advantageously, PLD produces films that have the same composition of the target. Further, PLD is easily optimized. For example, the laser energy, substrate temperature, and composition of the gases inside the vacuum chamber can be optimized to result in the desired deposition kinetics. In addition, PLD is a one step process that does not require a purging process. Accordingly, PLD is generally simpler and faster than methods that require a purging process, for example, ALD. PLD does not require a customized precursor source for calcite deposition, unlike ALD.

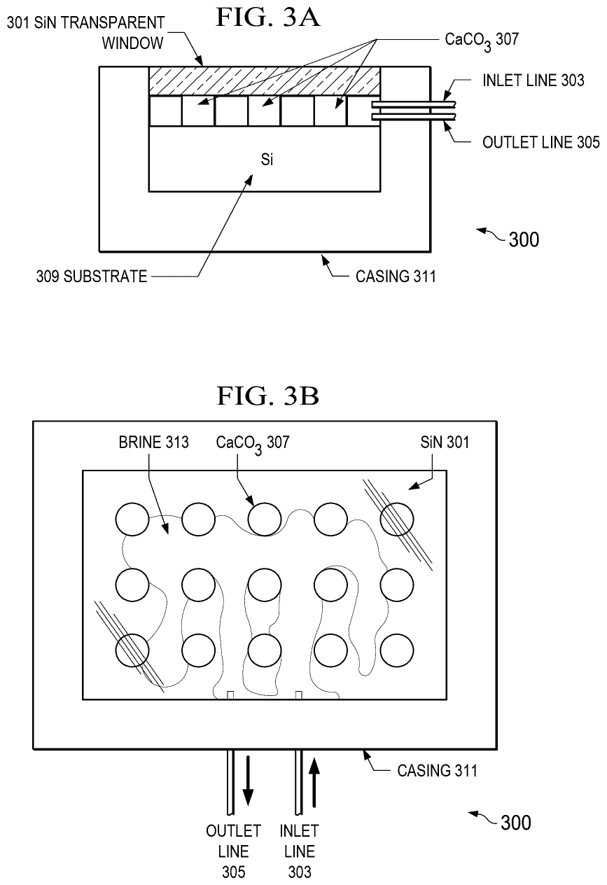

FIGS. 3A and 3B illustrate a cross-sectional view and a top view, respectively, of an example nanofluidic device 300. The device 300 includes a silicon substrate 309 and calcite channels 307. The calcite deposits that make up the channels 307 can have any shape, such as a cylinder or a cuboid. In addition to varying calcite deposit shapes, the pattern of the calcite channels 307 can be varied. For example, the channels 307 can have a stacked row pattern, where the center of each calcite deposit is in line with a center of a calcite deposit in a row directly above or a row directly below, as illustrated in FIG. 3B. In some implementations, the channels 307 can have a shifted row pattern, where the center of each calcite deposit is not in line with a center of any calcite deposit in a row directly above or a row directly below. The straight or curved edges of the calcite deposits and the channel pattern can represent a variety of geometries that occur in natural calcite reservoirs. In some implementations, the calcite channels 307 of the nanofluidic device 300 can have a length in a range of 50 to 100 nm in at least one dimension. For example, the width of each calcite channel 307 can be in the range of 50 to 100 nm.

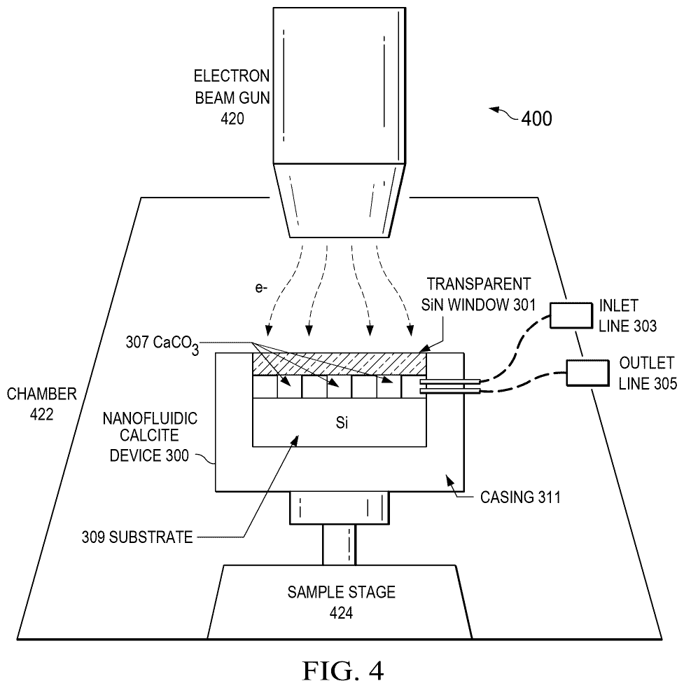

Still referring to FIGS. 3A and 3B, the silicon substrate 309 and the calcite channels 307 can be packaged in a casing 311 with a window 301 transparent to an electron beam on top of the calcite channels 307. In certain implementations, the casing 311 can be made of a conductive metal, and the window 301 can be made of an electrically conductive material that is also optically transparent, such as silicon nitride (SiN). Electrical conductivity allows the window 301 to avoid accumulating an electric charge, and the transparency of the window 301 allows observation. As illustrated, the casing has an inlet connection 303 that allows a fluid, such as brine solution 313, to enter the nanofluidic device 300 and an outlet connection 305 that allows fluid to exit. As shown in FIGS. 3A, 3B, and 4, the inlet connection 303 and outlet connection 305 can be located on the same side of device the 300. In some implementations, the inlet connection 303 and outlet connection 305 can be located on opposite or adjacent sides of the device 300.

FIG. 4 illustrates an example system 400 for testing a nanofluidic device 300. For example, the system 400 can image a reaction between the calcite channels 307 and a fluid. The nanofluidic device 300 is positioned on a sample stage 424 located inside a chamber 422. The chamber 422 can isolate the device 300 from outside interference and can be evacuated. Fluid, such as brine solution, can be introduced to the device by inlet connection 303 and the fluid can exit by outlet connection 305. As fluid flows into and out of the device 300, an electron beam gun 420 emits an electron beam to produce an image of the calcite channels 307 while interacting with the fluid. The electron beam gun 420, chamber 422, and sample stage 424 can be components of a single apparatus, such as an SEM. In certain implementations, the electron beam gun 420 is the same source of electrons used to perform electron beam lithography in fabricating the nanofluidic device 300, for example, a modified SEM capable of performing electron beam lithography.

Calcite reservoirs are typically heterogeneous. Some areas of the reservoir can contain large voids, whereas other areas can have poor connectivity and low permeability. Acid injection is an enhanced oil recovery method that can increase the connectivity of an area of a reservoir. Acid injection can include a brine solution 313 with acid content, for example 10% hydrochloric acid. Acid injection causes carbonate dissolution, and the dynamics of formation dissolution due to acid flow on a pore-scale and an atomic-scale can determine the net flow behavior. The dynamics can also determine other reservoir characteristics such as likelihood for leakage, oil and gas recovery, and storage capacity. As brine solution 313 flows through the nanofluidic device 300, the SEM can observe calcite dissolution and preferential flow of brine at a nanometer scale in the device 300. The observations can then be used to quantify acid dissolution of carbonates and to predict the migration of brine through aquifers, such as calcite formations.

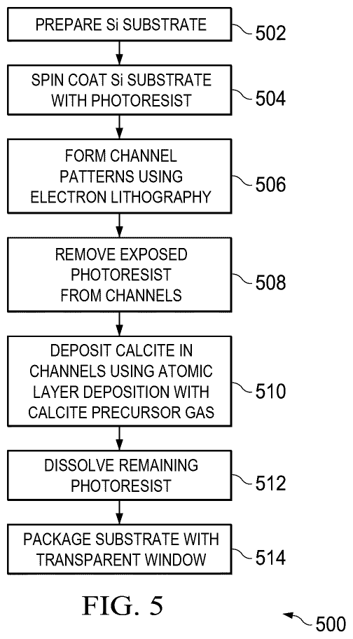

FIG. 5 is a flowchart illustrating an example method 500 for fabricating a calcite channel nanofluidic device. At 502, a silicon substrate is prepared to be the bottom of the nanofluidic device. The size and shape of the substrate can be matched to the size of a sample stage 424 of an SEM. In general, the nanofluidic device is packaged in a casing as described herein, and the size of the substrate is smaller than the sample stage 424. Substrate preparation can include cleaning of the substrate. At 504, photoresist is coated on the substrate, for example, by spin coating. A number of parameters can determine the thickness of the coated layer of photoresist such as a spin rate, photoresist viscosity, temperature, and other parameters. In some implementations, the thickness can equal a desired height of calcite channels in a nanofluidic device. In certain implementations, the photoresist is a negative photoresist, such as PDMS or SU-8. At 506, channel patterns are formed using electron beam lithography. Forming channel patterns involves exposing a portion of the photoresist to a beam of electrons, for example, from an SEM. At 508, the exposed portion of the photoresist is developed, that is, removed. Developing the photoresist generally involves dissolving the exposed portion of photoresist in solvent, such as PGMEA, ethyl lactate, or di-acetone alcohol. Developing the photoresists generally reveals the underlying portion of surface of the substrate. At 510, calcite is deposited in the channel patterns using atomic layer deposition with calcite precursor gas. Atomic layer deposition involves depositing calcite, layer by layer. In certain implementations, calcite is deposited layer by layer until the calcite channel height is similar to or the same as the original height of the photoresist coated on the substrate at 504. At 512, the remaining portion of photoresist is dissolved using a solvent. The calcite channel structure that is on the substrate-and the substrate itself-remain. The formed calcite channels can have heights in the range of 50 to 100 nm, lengths in the range of 50 to 100 nm, and widths in the range of 50 to 100 nm. At 514, the device, which includes the substrate and calcite channels, is packaged in a casing. The casing can include a top portion with a window, a bottom portion that holds the device, an inlet connection to allow a fluid to enter the device, and an outlet connection to allow the fluid to exit the device. The window can be made of an electrically conductive and optically transparent material, such as SiN, and can be set on top of the calcite channels deposited on the substrate. In certain implementations, the package includes a metal casing around the substrate.

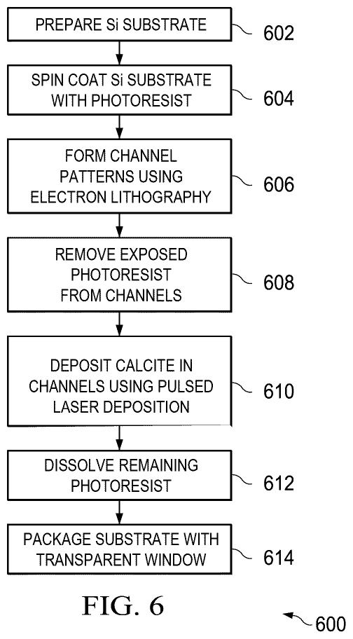

FIG. 6 is a flowchart illustrating an example method 600 for fabricating a calcite channel nanofluidic device. At 602, a silicon substrate is prepared to be the bottom of the nanofluidic device. The size and shape of the substrate can be matched to the size of a sample stage 424 of an SEM. In general, the nanofluidic device is packaged in a casing as described herein, and the size of the substrate is smaller than the sample stage 424. Substrate preparation can include cleaning of the substrate. At 604, photoresist is coated on the substrate, for example, by spin coating. A number of parameters can determine the thickness of the coated layer of photoresist such as a spin rate, photoresist viscosity, temperature, and other parameters. In some implementations, the thickness can equal a desired height of calcite channels in a nanofluidic device. In certain implementations, the photoresist is a negative photoresist, such as PDMS or SU-8. At 606, channel patterns are formed using electron beam lithography. Forming channel patterns involves exposing a portion of the photoresist to a beam of electrons, for example, from an SEM. At 608, the exposed portion of the photoresist is developed, that is, removed. Developing the photoresist generally involves dissolving the exposed portion of photoresist in a solvent, such as PGMEA, ethyl lactate, or di-acetone alcohol. Developing the photoresists generally reveals the underlying portion of surface of the substrate. At 610, calcite is deposited in the channel patterns using pulsed laser deposition. In certain implementations, calcite is deposited layer by layer until the calcite channel height is similar to or the same as the original height of the photoresist coated on the substrate at 604. At 612, the remaining portion of photoresist is dissolved using a solvent. The calcite channel structure that is on the substrate-and the substrate itself-remain. The formed calcite channels can have heights in the range of 50 to 100 nm, lengths in the range of 50 to 100 nm, and widths in the range of 50 to 100 nm. At 614, the device, which includes the substrate and calcite channels, is packaged in a casing. The casing can include a top portion with a window, a bottom portion that holds the device, an inlet connection to allow a fluid to enter the device, and an outlet connection to allow the fluid to exit the device. The window can be made of an electrically conductive and optically transparent material, such as SiN, and can be set on top of the calcite channels deposited on the substrate. In certain implementations, the package includes a metal casing around the substrate.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain this disclosure. Other changes, substitutions, and alterations are also possible without departing from the spirit and scope of this disclosure.

### Embodiments

In some implementations, a method of fabricating calcite channels in a nanofluidic device includes coating a photoresist on a substrate, exposing a portion of the photoresist to a beam of electrons, wherein the portion is exposed in a channel pattern, developing the exposed portion of the photoresist to form the channel pattern, depositing calcite in the channel pattern using pulsed laser deposition, and removing the photoresist remaining after developing the exposed portion of the photoresist.

In an example implementation combinable with any other example implementation, the substrate includes silicon.

In an example implementation combinable with any other example implementation, the photoresist includes a negative photoresist.

In an example implementation combinable with any other example implementation, the negative photoresist includes polydimethylsiloxane (PDMS) or SU-8.

In an example implementation combinable with any other example implementation, developing the photoresist includes dissolving the photoresist using a solvent and revealing a portion of the substrate.

In an example implementation combinable with any other example implementation, the solvent includes propylene glycol methyl ether acetate (PGMEA), ethyl lactate, or di-acetone alcohol.

In an example implementation combinable with any other example implementation, the method includes packaging the device in a casing, wherein the casing includes a top portion comprising a window, a bottom portion configured to hold the device, an inlet connection configured to allow a fluid to enter the device, and an outlet connection configured to allow the fluid to exit the device.

In an example implementation combinable with any other example implementation, the window includes an electrically conductive and optically transparent material, and optionally wherein the conductive and optically transparent material includes silicon nitride (SiN).

In an example implementation combinable with any other example implementation, depositing calcite in the channel pattern using pulsed laser deposition further includes placing a calcite target in a vacuum chamber, placing the substrate with the channel pattern in the vacuum chamber, wherein the substrate is oriented such that the channel pattern on the substrate faces the calcite target, depressurizing the vacuum chamber, and striking the calcite target with a pulsed laser to generate ionized calcite particles from the calcite target, wherein the ionized calcite particles are deposited in the channel pattern.

In an example implementation combinable with any other example implementation, the laser pulses from the pulsed laser are from 2 to 20 ns in duration.

In an example implementation combinable with any other example implementation, the laser pulses from the pulsed laser are conducted with a 10 Hz repetition rate, 7 ns pulse width, and a laser wavelength of 532 nm.

In an example implementation combinable with any other example implementation, depressurizing the vacuum chamber includes depressurizing the vacuum chamber to about 100 Pa or less.

In an example implementation combinable with any other example implementation, the deposited calcite includes heights in the range of approximately 50 to 100 nanometers.

In an example implementation combinable with any other example implementation, the deposited calcite includes lengths in the range of approximately 50 to 100 nanometers.

In an example implementation combinable with any other example implementation, the deposited calcite includes widths in the range of approximately 50 to 100 nanometers.

What is claimed is:

1. A method of fabricating calcite channels in a nanofluidic device, the method comprising:
coating a photoresist on a substrate;
exposing a portion of the photoresist to a beam of electrons, wherein the portion is exposed in a channel pattern;
developing the exposed portion of the photoresist to form the channel pattern;
depositing calcite in the channel pattern using pulsed laser deposition; and
removing the photoresist remaining after developing the exposed portion of the photoresist.

2. The method of claim 1, wherein the substrate comprises silicon.

3. The method of claim 1, wherein the photoresist comprises a negative photoresist.

4. The method of claim 3, wherein the negative photoresist comprises polydimethylsiloxane (PDMS) or SU-8.

5. The method of claim 1, wherein developing the photoresist comprises dissolving the photoresist using a solvent and revealing a portion of the substrate.

6. The method of claim 5, wherein the solvent comprises propylene glycol methyl ether acetate (PGMEA), ethyl lactate, or di-acetone alcohol.

7. The method of claim 1, further comprising packaging the device in a casing, wherein the casing comprises:
a top portion comprising a window;
a bottom portion configured to hold the device;
an inlet connection configured to allow a fluid to enter the device; and
an outlet connection configured to allow the fluid to exit the device.

8. The method of claim 7, wherein the window comprises an electrically conductive and optically transparent material, and optionally wherein the conductive and optically transparent material comprises silicon nitride (SiN).

9. The method of claim 1, wherein depositing calcite in the channel pattern using pulsed laser deposition further comprises:
placing a calcite target in a vacuum chamber;
placing the substrate with the channel pattern in the vacuum chamber, wherein the substrate is oriented such that the channel pattern on the substrate faces the calcite target;
depressurizing the vacuum chamber; and
striking the calcite target with a pulsed laser to generate ionized calcite particles from the calcite target, wherein the ionized calcite particles are deposited in the channel pattern.

10. The method of claim 9, wherein the laser pulses from the pulsed laser are from 2 to 20 ns in duration.

11. The method of claim 9, wherein the laser pulses from the pulsed laser are conducted with a 10 Hz repetition rate, 7 ns pulse width, and a laser wavelength of 532 nm.

12. The method of claim 9, wherein depressurizing the vacuum chamber comprises depressurizing the vacuum chamber to about 100 Pa or less.

13. The method of claim 1, wherein the deposited calcite includes heights in the range of approximately 50 to 100 nanometers.

14. The method of claim 1, wherein the deposited calcite includes lengths in the range of approximately 50 to 100 nanometers.

15. The method of claim 1, wherein the deposited calcite includes widths in the range of approximately 50 to 100 nanometers.
